(19) United States
(12) Patent Application Publication
(10) Pub. No.: US 2001/0036730 A1
(43) Pub. Date: Nov. 1, 2001

(54) METHOD FOR FABRICATING A DRAM CELL CAPACITOR

(76) Inventor: JEONG-SEOK KIM, JANGMI TOWN (KR)

Correspondence Address: SKJERVEN MORRILL MACPHERSON LLP, 25 METRO DRIVE, SUITE 700, SAN JOSE, CA, 95110, US

(21) Appl. No.: 09/342,320

(22) Filed: Jun. 29, 1999

(30) Foreign Application Priority Data
Jul. 6, 1998 (KR) 1998-27085

(51) Int. Cl. H01L 21/302; H01L 21/461

(52) U.S. Cl. 438/689

(57) ABSTRACT

A method for manufacturing a capacitor of a semiconductor device is disclosed. The method includes: forming an insulating layer on a semiconductor substrate; forming a pattern layer (typically patterned silicon layer) on the insulating layer; etching the insulating layer using the pattern layer as a mask so as to form a contact hole through the insulating layer; forming a conductive layer on the insulating layer so as to fill the contact hole; removing the conductive layer and the material pattern layer to expose the insulating layer but leave a contact plug in the opening; forming an amorphous silicon pattern layer connecting to the contact plug; and forming a hemispherically grained (HSG) layer on the amorphous silicon pattern layer. The material pattern layer is formed by forming a material layer having etching selectivity different from etching selectivity of the insulating layer and etching the material layer to form an opening through the material layer. The opening exposes the insulating layer and has a sloped side wall. An upper portion of the opening is wider than a lower portion of the opening. By removing the pattern layer, a thick amorphous silicon pattern layer can be used for cell storage nodes and provide a greater area for the HSG layer.

### FIELD OF THE INVENTION

The present invention relates to a method for manufacturing a semiconductor device, and more particularly to a method for fabricating a capacitor having hemispherically grained silicon layer.

### BACKGROUND OF THE INVENTION

As the integration of integrated circuit devices increases, the area available for a cell capacitor in a device decrease. However, in memory devices such as DRAM, cell capacitor must meet a minimum requirement of capacitance because the capacitance of the cell capacitor affects the characteristics and reliability of a memory device.

One method of forming a capacitor in a limited area without reducing the capacitance uses a high dielectric material as a dielectric film of the capacitor. Such capacitor formation requires fairly complicated manufacturing processes. An alternative method increases surface area of a capacitor by using a three-dimensional storage node. For this purpose, various three-dimensional stacked capacitor structures have been suggested, including double-stacked, fin stacked, cylindrical, and box structures.

Another method for increasing the surface area of a storage node uses a hemispherically grained (HSG) polysilicon layer in forming the storage node. The HSG polysilicon layer can be formed by controlled nucleation and growth of polysilicon to modify the surface morphology of the storage node, increasing the surface area of the storage node.

The limited cell capacitor area in a semiconductor device presents another problem in manufacturing the device. In particular, the capacitor in a DRAM cell electrically connects to a source/drain region of a transistor via a contact opening through an insulating layer. However, the reduced cell area increases aspect ratio of the contact opening. Formation of a contact opening having a very high aspect ratio requires improved photolithography methods.

FIGS. 1A to 1D illustrate a conventional method for fabricating a capacitor in a semiconductor device. Referring to FIG. 1A, a transistor 15, a first oxide layer 16a, a bit line 17, and a second oxide layer 16b are sequentially formed on a semiconductor substrate 10. Then, a first amorphous silicon layer 18 is formed, and a photoresist pattern layer (not shown) is formed on polysilicon layer 18, exposing a portion of silicon layer 18 for a contact hole 19. Using the photoresist pattern layer as a mask, silicon layer 18 is etched to leave a sloped etched surface in silicon layer 18. Further etching of an oxide layer 16 formed from oxide layers 16a and 16b uses etched silicon layer 18 as a mask and forms contact hole 19 having a smaller diameter than is defined by the photoresist pattern layer. In addition, a silicon nitride spacer 20 is formed on the sidewall of contact hole 19 by depositing silicon nitride. The deposition is performed at a high temperature, transforming silicon layer 18 from amorphous silicon to polysilicon.

Referring to FIG. 1B, a second amorphous silicon layer is formed on polysilicon layer 18 so as to fill contact hole 19. Then, the second amorphous silicon layer and polysilicon layer 18 are sequentially photo-etched to form a storage node 22 of a capacitor.

Referring to FIG. 1C, after forming storage node 22, a HSG silicon layer 23 is formed on storage node 22, which is made of amorphous silicon. HSG silicon layer 23 does not form on the surface of polysilicon layer 18. Finally, referring to FIG. 1D, a dielectric film 24 and an upper electrode 25 of the capacitor are formed to complete the capacitor.

As shown in FIG. 1C, HSG silicon layer is not formed on a surface of a polysilicon layer that was transformed from amorphous silicon during silicon nitride layer formation. Accordingly, a storage node without the polysilicon layer may achieve a greater surface area by having a larger HSG silicon area.

### SUMMARY OF THE INVENTION

The present invention is directed toward fabricating a DRAM cell capacitor that has an increased surface area and capacitance within a given cell area. One feature of the present invention is the formation of a contact hole using a relaxed photo-etching process. The photo-etching process uses a polysilicon mask that has an etching selectivity with respect to an underlying insulating layer. After forming the contact hole, a silicon nitride spacer is formed in the contact hole and on the polysilicon mask. After that, a conductive material is deposited in the contact hole and on the polysilicon mask. A planarization process removes the conductive material and the polysilicon mask, exposing the insulating layer and a contact plug formed from the conductive material that remains in the contact hole. Another material on which HSG silicon is to be grown is then deposited on the insulating layer and patterned to form a storage node in electrical contact with the contact plug. HSG silicon is then formed on the entire surface of the storage node.

One embodiment of the present invention provides a method for manufacturing a capacitor of a semiconductor device. The method includes: forming an insulating layer on a semiconductor substrate; forming a pattern layer on the insulating layer; etching the insulating layer exposed through the pattern layer so as to form a contact hole through the insulating layer, the contact hole exposing a portion of a top surface of the semiconductor substrate; forming a conductive layer on the insulating layer so as to fill the contact hole; removing the conductive layer and the pattern layer to the extent that the insulating layer is exposed, leaving a portion of the conductive layer in the contact hole to form a contact plug; forming an amorphous silicon pattern layer connecting to the contact plug on the exposed insulating layer; and forming a hemispherically grained (HSG) layer on a surface of the amorphous silicon pattern layer.

The pattern layer is formed by forming a material layer having etching selectivity different from etching selectivity of the insulating layer and etching the material layer to form an opening through the material layer. The opening exposes the insulating layer and has a sloped side wall, with an upper portion of the opening being wider than a lower portion of the opening.

### BRIEF DESCRIPTION OF THE DRAWINGS

The features and advantages of the invention will become apparent to those skilled in the art by describing specific embodiments with reference to the accompanying drawings, which are:

FIGS. 1A to 1D are cross-sectional views of a semiconductor device, illustrating a conventional method for manufacturing a capacitor of the device; and

FIGS. 2A to 2E are cross-sectional views of a semiconductor device, illustrating a method for manufacturing a capacitor of the device according to an embodiment the present invention.

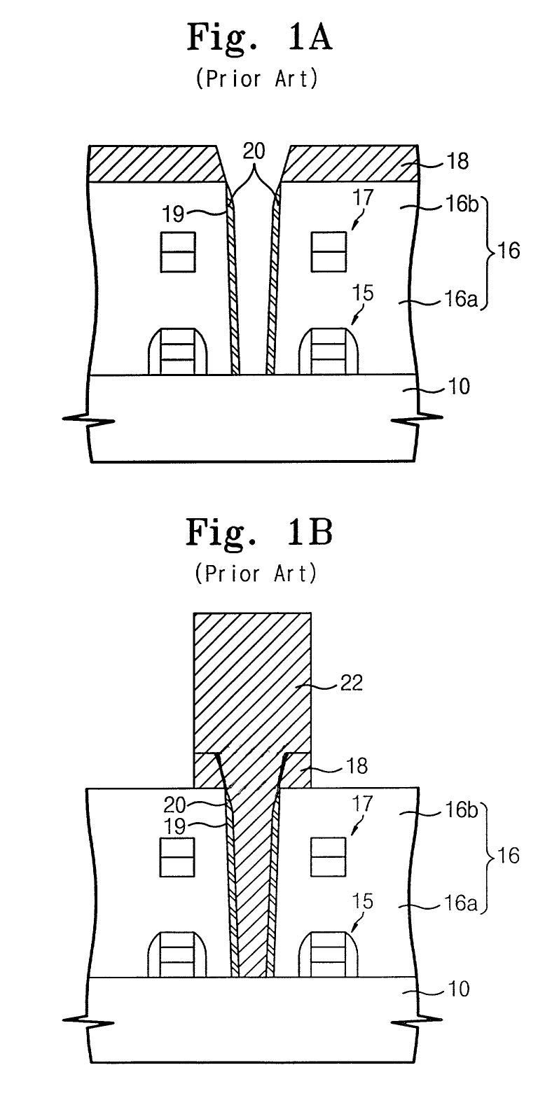

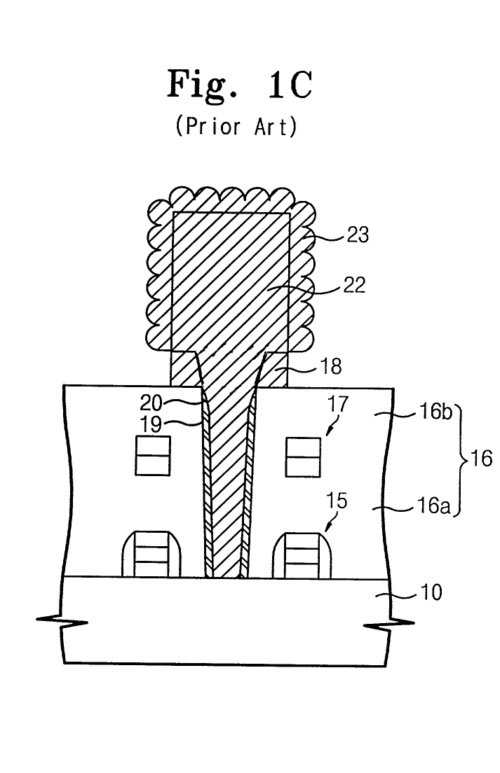

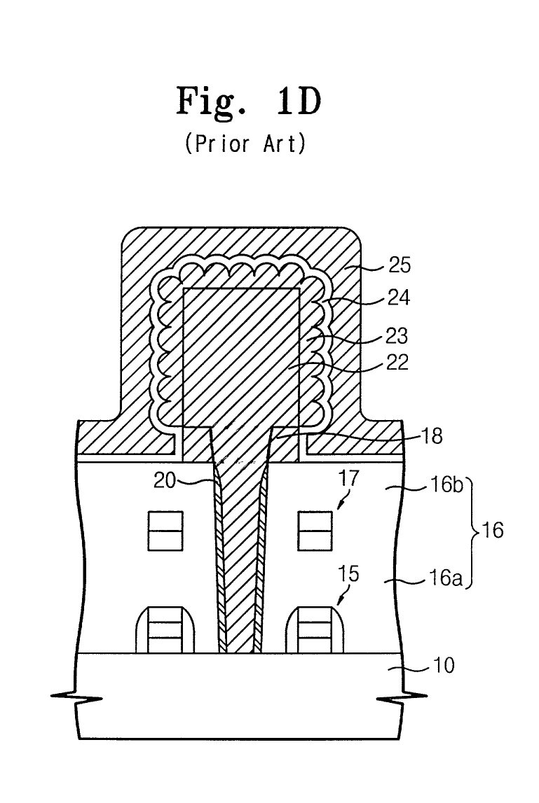

Use of the same reference symbols in different figures indicates identical or similar items.

### DETAIL DESCRIPTION OF THE PREFERRED EMBODIMENTS

An aspect of the present invention provides a method for manufacturing a cell capacitor having an HSG silicon layer that is applicable to highly integrated circuit devices. The method includes multiple process steps to form the cell capacitor, and some of the process steps, such as forming a field oxide layer and a transistor structure, are similar to those presently practised for manufacturing DRAM cells in the industry.

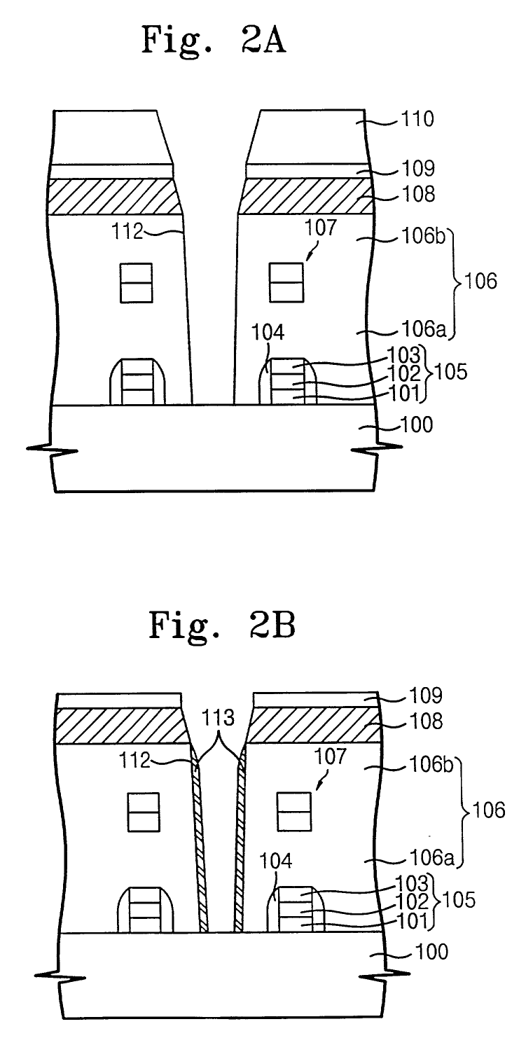

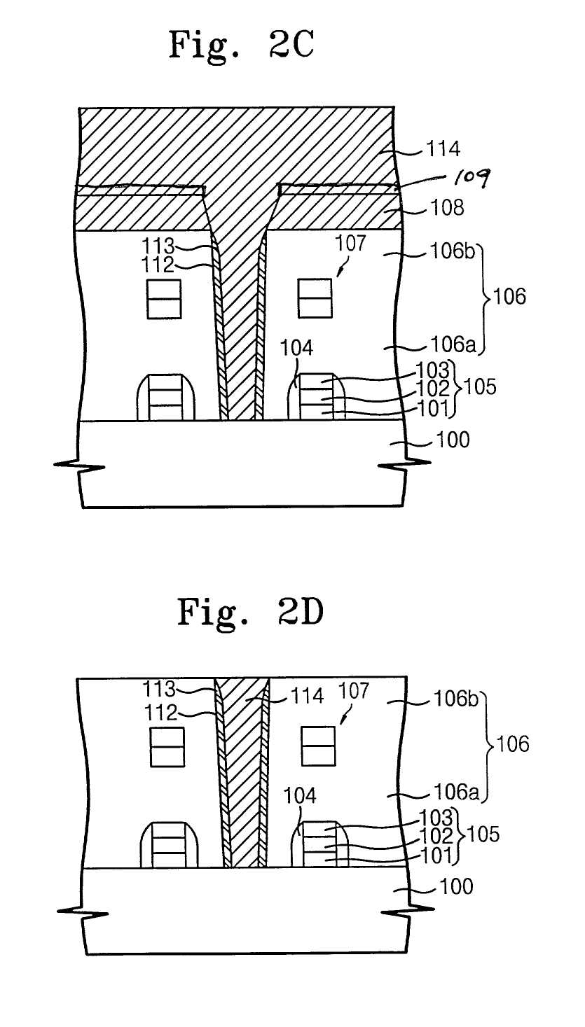

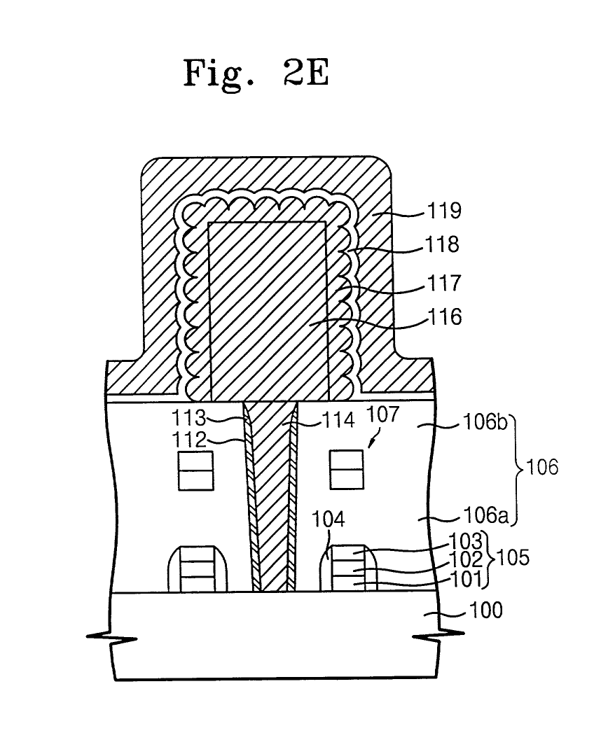

FIGS. 2A to 2E illustrates a method for manufacturing a cell capacitor in accordance with an embodiment of the present invention. Referring to FIG. 2A, a transistor 105 is formed on a semiconductor substrate 100. Transistor 105 includes a gate oxide layer (not shown), a gate electrode layer composed of a polysilicon layer 101 and a silicide layer 102, a silicon nitride capping layer 103, silicon nitride spacers 104, and a pair of source/drain regions (not shown) in substrate 100. On semiconductor substrate 100 including transistor 105 thereon, a first oxide layer 106a is formed, and a bit line 107 is formed on first oxide layer 106a. Then, a second oxide layer 106b is formed on bit line 107 and first oxide layer 106a. The formation of second oxide layer 106b makes substrate 100 covered with an oxide layer 106 consisting of first and second oxide layers 106a and 106b.

Now a contact hole 112 is formed through oxide layer 106 so as to expose a portion of substrate 100. For forming contact hole 112, an amorphous silicon layer 108 is formed on second oxide layer 106b to 50 nm to 300 nm. Then, a 20-60 nm thick anti-reflection coating layer 109 and a photoresist pattern layer 110 are sequentially formed on amorphous silicon layer 108. Photoresist pattern layer 110 exposes a portion of anti-reflection coating layer 109 associated with contact hole 112.

After the formation of photoresist pattern layer 110, a known etching method, using photoresist pattern layer 110 as an etching mask, etches anti-reflection coating layer 109 and amorphous silicon layer 108. The etching forms an opening which exposes oxide layer 106 and has a vertical sidewall in anti-reflection coating layer 109 and a sloped sidewall in amorphous silicon layer 108 as shown in FIG. 2A. Then, using amorphous silicon layer 108 as a mask, insulting layer 106 is anisotropically etched to form contact hole 112 having a substantially vertical sidewall. The sloping side wall of the opening in silicon layer 108 causes, contact hole 112 in oxide layer 108 to be narrower than the opening defined by photoresist pattern layer 110.

Referring to FIG. 2B, after the contact hole formation, photoresist pattern layer 110 is removed, and LPCVD (low pressure chemical vapor deposition) forms a silicon nitride spacer 113 on the sidewall of contact hole 112 to 10-30 nm. The formation of spacer 113 transforms amorphous silicon layer 108 into crystalline silicon (polysilicon). Nitride spacer 113 prevents an electrical short between bit line 107 and a contact plug to be formed in contact hole 112.

Referring to FIGS. 2C and 2D, a conductive material layer 114 is formed on anti-reflection coating layer 109 and fills contact hole 112. Conductive layer 114 is 100 nm to 300 nm thick and made of doped polysilicon. Then, a known planarization process, such as chemical mechanical polishing or dry etching, removes conductive material layer 114, anti-reflection coating layer 109 and crystallized silicon layer 108. The dry etching is preferably a process having a high etch rate for silicon layer 108 and a low etch rate for oxide layer 106. The resulting structure, shown in FIG. 2D, includes planarized second oxide layer 106b with a contact plug 114 formed in contact hole 112. Unlike the method described in the prior art, this method removes crystallized silicon layer 108.

Referring to FIG. 2E, after the planarization, a 0.7 to 1.2 μm thick amorphous silicon layer is formed on second oxide layer 106b. Then, a known photo-etch process etches the amorphous silicon layer to form a storage node 116, and an HSG silicon layer 117 is formed on the entire surface of storage node 116 through known nucleation and growth processes. After forming HSG silicon layer 117, a dielectric film 118 and an upper electrode 119 are formed. Dielectric film 118 can be made of Ta₂O₅.

Although the invention has been described with reference to particular embodiments, the description is only an example of the inventor's application and should not be taken as a limitation. Various adaptations and combinations of features of the embodiments disclosed are within the scope of the invention as defined by the following claims.

What is claimed is:

1. A method for fabricating a capacitor of a semiconductor device, comprising:
forming an insulating layer on a semiconductor substrate;
forming a material layer on said insulating layer, said material layer having an etching selectivity with respect to said insulating layer;
etching said material layer down to a top surface of said insulating layer to from a first opening;
using said material layer as a mask and etching said insulating layer exposed by said first opening down to a top surface of said substrate to form a second opening;
forming an insulating spacer on sidewalls of said second opening;
depositing a conductive layer in a remainder of said second opening and over said material layer;
removing said conductive layer and said material layer to expose said insulating layer and leave a portion of said conductive layer that is in said second opening to form a contact plug;
forming an amorphous silicon pattern layer connecting to said contact plug on said exposed insulating layer; and
forming a hemispherically grained (HSG) layer on a surface of said amorphous silicon pattern layer.

2. The method according to claim 1, wherein said material layer comprises polysilicon.

3. The method according to claim 1, wherein said insulating spacer comprises silicon nitride.

4. The method according to claim 1, wherein said material layer has a thickness in a range from 50 nm to 300 nm and said insulating spacer has a thickness in a range from 10 nm to 30 nm.

5. The method according to claim 1, wherein said conductive layer comprises polysilicon and has a thickness in a range from 100 nm to 300 nm.

6. The method according to claim 1, wherein said removing of said conductive layer and said material layer comprises chemical mechanical polishing.

7. The method according to claim 1, wherein removing said conductive layer and said material layer comprises dry etching.

8. The method according to claim 1, wherein said amorphous silicon pattern layer has a thickness in a range from 0.7 μm to 1.2 μm.

9. The method according to claim 1, further comprising forming a dielectric film and a plate node conductive layer to form a capacitor.
